(19) United States
(12) Patent Application Publication
(10) Pub. No.: US 2013/0071967 A1
(43) Pub. Date: Mar. 21, 2013

(54) Method for Making a Nickel Film for Use as an Electrode of an N-P Diode or Solar Cell

(71) Applicants: Yu-Han Su, Taoyuan County (TW); Wei-Yang Ma, New Taipei City (TW); Tsun-Neng Yang, Taipei City (TW)

(72) Inventors: Yu-Han Su, Taoyuan County (TW); Wei-Yang Ma, New Taipei City (TW); Tsun-Neng Yang, Taipei City (TW)

(73) Assignee: ATOMIC ENERGY COUNCIL-INSTITUTE OF NUCLEAR ENERGY RESEARCH, TAOYUAN COUNTY (TW)

(21) Appl. No.: 13/238,122

(22) Filed: Sep. 21, 2011

(51) Int. Cl. H01L 21/283; H01L 31/18

(52) U.S. Cl. 438/98; 438/678; 257/E21.159; 257/E31.124

(57) ABSTRACT

Disclosed is a method for making a nickel film for use as an electrode of an n-p diode or solar cell. A light source is used to irradiate an n-type surface of the n-p diode or solar cell, thus producing electron-hole pairs in the n-p diode or solar cell. For the electric field effect at an n-p interface, electrons drift to and therefore accumulate on the n-type surface. With a plating agent, the diode voltage is added to the chemical potential for electroless plating of nickel on the n-type surface. The nickel film can be used as a buffer layer between a contact electrode and the diode or solar cell. The nickel film reduces the contact resistance to prevent a reduced efficiency of the diode or solar cell that would otherwise be caused by diffusion of the atoms of the electrode in following electroplating.

### BACKGROUND OF INVENTION

1. Field of Invention

The present invention relates to a method for making a nickel film that can be used as an electrode of an n-p diode or solar cell and, more particularly, to a method for electroless plating nickel on the n-type surface of an n-p diode or solar cell.

2. Related Prior Art

In conventional electroless (or “chemical”) plating of nickel, there is used a plating agent that includes a metal salt, a reducing agent and a complexing agent or stabilizer. Metal ions react with the reducing agent on a catalyzed surface and are therefore reduced to metal on the catalyzed surface.

On early days, the electrodes of solar cells were vacuum evaporated by E-gun evaporators. However, the solar cells must be moved into and out of the E-gun evaporators, and it was therefore difficult to subject the solar cells to mass production.

In 1975, screen printing was first used to make the electrodes of solar cells. As the technology has come a long way since then, most of the electrodes of solar cells are made by screen printing now. The screen printing of the electrodes is simple and fast and can easily be executed in a production line. The efficiency of the screen printing is close to the efficiency of the vacuum evaporation. However, the silver of silver colloid used in the screen printing is extremely expensive, and the price of silver has been skyrocketing recently. Therefore, for manufacturers who pursuit to reduce the costs of the solar cells, it is disadvantageous to make the electrodes of solar cells by screen printing in which silver colloid is used. There is a strong incentive to develop a low-cost process for making the electrodes of solar cells from a low-cost material.

There have been efforts to make positive electrodes of nickel/copper. At first, electroless plating of nickel is executed. Then, electroplating of copper is conducted. There are several advantages. At first, nickel and copper are less expensive than silver used in the screen printing. Secondly, the width of the electrodes made of nickel/copper can be smaller than the width of the electrodes made of silver in the screen printing. Thirdly, nickel and silicon substrates can be subjected to heat treatment and therefore form Ni-silicide that exhibits a low contact resistance.

Electroless plating of nickel was first developed in 1946 by Brenner and Riddell. While trying to electroplate nickel on iron, they found that the efficiency of the cathode current exceeded 100% because of the addition of a reducing agent, sodium hypophosphite. Later, it was found that sodium hypophosphite reduces nickel ions to nickel on a catalyzing metal surface. They have applied for and obtained patents related to the electroless plating of nickel. Currently, for a non-catalyzing surface of an object on which electroless plating is desired, the surface is processed with palladium (“Pd”) beforehand. However, for ohm contact metal used in metal-semiconductor, palladium affects its contact efficiency.

In typical electroless plating, a reducing agent included in a plating agent reduces a catalyzing surface to reduce metal ions to metal so that the metal is provided on the surface by electroless plating. Metal cannot be provided on a surface by electroless plating, if the surface is not catalyzing. Currently, in a mature catalyzing process, a layer of palladium is plated on a surface before a reducing agent reduces metal ions to metal on the surface by electroless plating. However, the electroless plating is only good for making a surface of metal wear-resistant, erosion-resistant and aesthetically pleasant. For a surface of metal that must exhibit an excellent ohm contact effect, palladium affects the forming of the Ni-silicide during the heat treatment and therefore affects the ohm contact effect.

Therefore, there are incentives for other methods for processing a surface of metal. A thin oxide layer may be grown on the surface of metal or hydrogen may be attached or bonded to the surface of metal. The oxide grown on the surface of metal considerably affects the ohm contact effect. The hydrogen attached or bonded to the surface of metal seems to be better processes than the oxide grown on the surface of metal regarding the ohm contact effect. However, the attachment or bond of the hydrogen to the surface of metal is a time-consuming process. In addition, if it is desired to confine the electroless plating in a certain area with a certain pattern, it will require quite a few additional processes to provide protective masks on areas wherein the electroless plating is not desired. The nickel/copper electrodes made by the electroless plating are better than the silver electrodes made by the screen printing regarding the costs of the materials and the contact resistance. It is however not easy to implement the electroless plating in a production line because it is complicated.

To our best understanding, there has not been any method for electroless plating nickel on the surface of semiconductor that can be used as ohm contact metal.

The present invention is therefore intended to obviate or at least alleviate the problems encountered in prior art.

### SUMMARY OF INVENTION

It is an objective of the present invention to provide an efficient method for making an inexpensive and quality electroless plated metal film on the n-type surface of an n-p diode or solar cell without having to experience problems with surface-processing of the n-p diode or solar cell.

It is another objective of the present invention to provide a method for making an electroless plated nickel film for use as a buffer layer between a contact electrode and an n-p diode or a solar cell while reducing contact resistance and preventing diffusion of the atoms of an electrode used in a subsequent electroplating process that would otherwise result in a reduced efficiency of the diode or solar cell.

It is another objective of the present invention to provide a method for making an electroless plated metal film without having to use a reducing agent that would otherwise require high temperature.

It is another objective of the present invention to provide a method for making an electroless plated metal film by using electrons released from an n-p diode or solar cell to reduce metal ions so that there is a strong bond between the electroless plated film and the n-p diode or solar cell.

It is another objective of the present invention to provide a method for making an electroless plated metal film that is confined by a mask that can simply and easily be designed.

It is another objective of the present invention to provide a method for making an electroless plated metal film on only an n-type surface of an n-p diode or solar cell without having to provide any protection on a p-type surface of the n-p diode or solar cell.

It is another objective of the present invention to provide a method for making an electroless plated metal film without having to provide any electric bias.

To achieve the foregoing objectives, the method of the present invention provides a light source to irradiate the n-type surface of the n-p diode or solar cell to produce electron-hole pairs in the n-p diode or solar cell. At the same time, because of the electric field effect at the n-p interface, the electrons drift to and therefore accumulate on the n-type surface. With a plating agent, a diode voltage and a chemical potential are added up for the electroless plating of nickel only on the n-type surface.

Other objectives, advantages and features of the present invention will be apparent from the following description referring to the attached drawings.

### BRIEF DESCRIPTION OF DRAWINGS

The present invention will be described via detailed illustration of the preferred embodiment referring to the drawings wherein:

FIG. 1 is a flow chart of a method for making a nickel film of an electrode via electroless plating in accordance with the preferred embodiment of the present invention;

FIG. 2 is a side view of a piece of equipment for executing the method shown in FIG. 1; and

FIG. 3 is a schematic view of the electroless plating of the method shown in FIG. 1.

### DETAILED DESCRIPTION OF PREFERRED EMBODIMENT

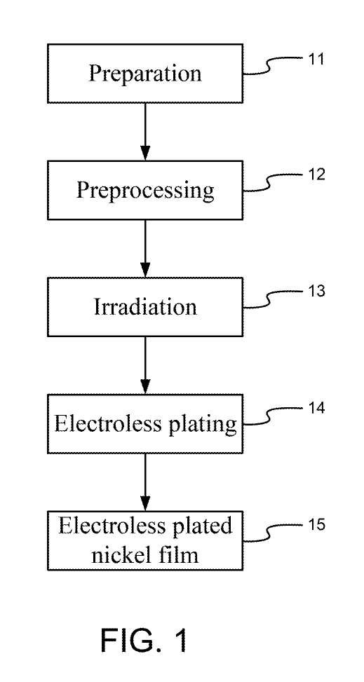

Referring to FIGS. 1 through 3, there is shown a method for making a nickel film for use as an electrode of an n-p diode or solar cell in accordance with the preferred embodiment. A light source is used to irradiate the n-type surface of the n-p diode or solar cell to produce electron-hole pairs in the n-p diode or solar cell. At the same time, because of the electric field effect at the n-p interface, electrons drift to and therefore accumulate on the n-type surface. With a plating agent, a diode voltage and a chemical potential are added up for the electroless plating of the nickel film. The resultant electroless plated nickel film exists only on the n-type surface. It should be noted that there is no need for a reducing agent and there is no need for catalysis on the surface of a substrate.

The method for electroless plating nickel on the n-type surface of an n-p diode or solar cell can be executed by taking the following steps.

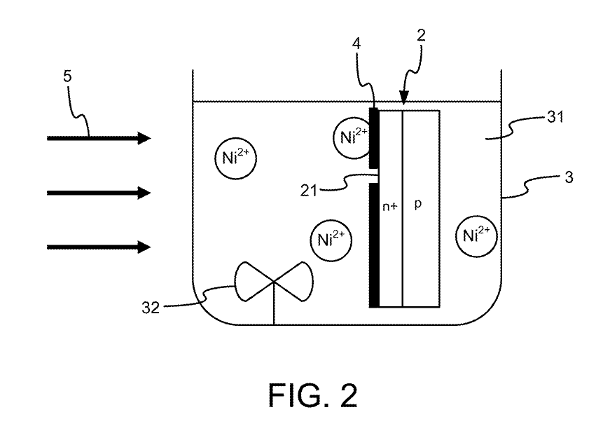

At 11, preparation is made. With reference to FIG. 2, an n-p diode or solar cell 2 and a tank 3 are provided. The tank 3 is filled with an electroless plating agent 31. An agitator 32 is located in the tank 3. During the entire process, the agitator 32 is turned on to agitate constantly.

At 12, preprocessing is executed. The n-p diode or solar cell 2 is subjected to a standard surface-washing process. Then, the n-p diode or solar cell 2 and a mask 4 are located in the tank 3 while the agitation continues in the tank 3. The mask 4 is directly adhered to an n-type surface 21 of the n-p diode or solar cell 2 or just located in front of the n-type surface 21 of the n-p diode or solar cell 2.

At 13, a light source 5 is provided. The light source 5 is used to irradiate the n-type surface 21 of the n-p diode or solar cell 2.

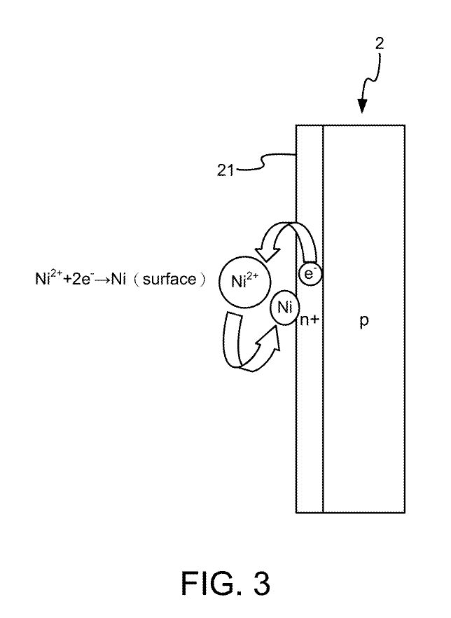

At 14, electroless plating of nickel is executed. With reference to FIG. 3, reduction occurs between the nickel ions (Ni²⁺) included in the electroless plating agent 31 contained in the tank 3 and electrons (e⁻) released from the n-type surface 21 of the n-p diode or solar cell 2. Hence, nickel (Ni) is electroless plated on the n-type surface 21 of the n-p diode or solar cell 2.

At 15, an electroless plated nickel film is made. The electroless plating lasts for 1 to 10 minutes. Then, the light source 5 is turned off. The thickness of the electroless plated nickel film is 0.1 to 1.0 μm. After the electroless plating, the n-p diode or solar cell 2 is removed from the tank 3, washed and dried. Now, the process is completed.

The electroless plating agent 31 is preferably a solution including nickel chloride, nickel sulfate or nickel acetate and potassium hydroxide, sodium hydroxide, ammonium chloride or citrates. The nickel chloride, nickel sulfate or nickel acetate is used for providing nickel. The light source 5 may be a halogen lamp. The n-p diode or solar cell 2 is washed by pure water (DI water) for three minutes and then dried by a nitrogen gun.

The entire method takes about 1 to 10 minutes except for the washing. The method exhibits several advantageous features.

At first, the reduction and electroless plating of the metal occur on the irradiated area of the n-type surface 21 of the n-p diode or solar cell 2 without having to include any reducing agent in the electroless plating agent 31. Without any reducing agent, it is not necessary to heat and keep the plating agent 31 at high temperature of 80° C. to 90° C. Therefore, the temperature at which the method is executed can be low.

Secondly, the metal ions included in the plating agent 31 are reduced by the electrons released from the semiconductor such as the n-p diode and the solar cell so that there is a strong bond between the electroless plated metal film and the semiconductor. Hence, the electroless plated metal film cannot easily be peeled from the semiconductor.

Thirdly, the reduction occurs to produce electron-hole pairs only in the area irradiated by the light source 5. Therefore, by the mask 4 that can easily be designed and made, protected is the area in which no electroless plating is supposed to occur, without having to execute a complicated process for providing photo-resist. That is, the area, in which the electroless plating is to be conducted, is confined. Hence, the electroless plating is highly selective.

Fourthly, the electroless plating of the metal only occurs on the n-type surface of the n-p diode or solar cell 2. No electroless plating occurs on the p-type surface without having to provide a mask or photoresist on the p-type surface to prevent electroless plating.

Fifthly, there is no need to provide any electric bias on the equipment.

Sixthly, the intensity of the light emitted from the light source can be adjusted to adjust the rate of the electroless plating.

As discussed above, inexpensive and quality electroless plated metal film is made efficiently and simply by the method of the present invention. The method of the present invention can be used in the manufacturing of semiconductor such as n-p diodes, solar cells and other photoelectric elements without having to experience problems with the processing of the surface of the semiconductor. The resultant electroless plated nickel film can be used as a buffer layer between the contact electrode and the n-p diode or solar cell. Furthermore, the resultant electroless plated nickel film can reduce the contact resistance and prevent diffusion of the atoms of an electrode used in a subsequent electroplating process that would result in a reduced efficiency of the n-p diode or solar cell 2.

The present invention has been described via the detailed illustration of the preferred embodiment. Those skilled in the art can derive variations from the preferred embodiment without departing from the scope of the present invention. Therefore, the preferred embodiment shall not limit the scope of the present invention defined in the claims.

1. A method for making a nickel film of an electrode including the steps of:
providing an n-p diode or solar cell 2 and a tank 3 in which an electroless nickel-plating agent 31 is filled and an agitator 32 is provided;
locating the n-p diode or solar cell 2 and a mask 4 in the tank 3 filled with the electroless nickel-plating agent 31, wherein the mask 4 is directly adhered to the an n-type surface 21 of the n-p diode or solar cell 2 or just located in front of the n-type surface 21 of the n-p diode or solar cell 2;
providing a light source to irradiate the n-type surface 21 of the n-p diode or solar cell 2;
reducing nickel ions in the tank 3 by electrons released from an area of the n-type surface 21 of the n-p diode or solar cell 2 irradiated by the light source 5, thus electroplating a nickel film on the n-type surface 21 of the n-p diode or solar cell 2; and
turning off the light source 5 after executing the electroless plating of the nickel film for 1 to 10 minutes, thus providing an electroless plated nickel film about 0.1 to 1.0 μm thick; and
removing the n-p diode or solar cell 2 from the tank 3 and washing and drying the the n-p diode or solar cell 2.

2. The method for making a nickel film of an electrode in accordance with claim 1, wherein the electroless plating agent 31 is a solution that contains a material selected from the group consisting of nickel chloride, nickel sulfate and nickel acetate and another material selected from the group consisting of potassium hydroxide, sodium hydroxide, ammonium hydroxide and citrates.

3. The method for making a nickel film of an electrode in accordance with claim 1, further including the step of executing standard surface-washing on the n-p diode or solar cell 2 before the n-p diode or solar cell 2 is located in the tank 3.

4. The method for making a nickel film of an electrode in accordance with claim 1, wherein the light source 5 is a halogen lamp.

5. The method for making a nickel film of an electrode in accordance with claim 1, wherein the n-p diode or solar cell 2 is washed by pure water (DI water) and dried by a nitrogen gun.
